(19) United States
(12) Patent Application Publication
(10) Pub. No.: US 2024/0395644 A1
(43) Pub. Date: Nov. 28, 2024

(54) GLASS-BASED INTEGRATED CIRCUIT PACKAGES FOR COMPOUND MICROELECTRONIC COMPONENTS OPERATING AT MILLIMETER WAVE (MMWAVE) FREQUENCIES

(71) Applicant: CORNING INCORPORATED, CORNING, NY (US)

(72) Inventors: Choonkon Kim, Cheonan-si (KR); Hyung Soo Moon, Seoul (KR); Jong-min Yook, Seongnam-si (KR)

(21) Appl. No.: 18/669,819

(22) Filed: May 21, 2024

Related U.S. Application Data
(60) Provisional application No. 63/468,329, filed on May 23, 2023.

(51) Int. Cl. H01L 23/15; H01L 23/31; H01L 23/48; H01L 23/498

(52) U.S. Cl. CPC H01L 23/15; H01L 23/3171; H01L 23/481; H01L 23/49822; H01L 23/49838; H01L 23/49872

(57) ABSTRACT

An integrated circuit package is disclosed. The integrated circuit package includes a glass substrate with a glass cladding layer fused to a glass core layer. The glass substrate includes a cavity with a floor defined by the glass core layer and a sidewall defined by the glass cladding layer. The integrated circuit package further includes a metal layer configured to define a continuous path of thermally and electrically conductive material. The metal layer is disposed within the cavity and along a first surface of the glass cladding layer. The first surface faces opposite an interface between the glass core layer and the glass cladding layer. The integrated circuit package further includes an integrated circuit chip disposed within the cavity and contacting a portion of the metal layer within the cavity. The metal layer provides thermal and electrical connection to a bottom (encapsulated) side of the integrated circuit chip.

### CROSS-REFERENCE TO RELATED APPLICATIONS

This application claims the benefit of priority under 35 U.S.C. § 119 of U.S. Provisional Application No. 63/468,329 filed May 23, 2023, the content of which is incorporated herein by reference in its entirety.

### FIELD

The present disclosure relates to integrated circuit packaging and, more particularly, to glass-based integrated circuit packages for compound microelectronic components operating at millimeter wave (mmWave) frequencies.

### BACKGROUND

Molding compounds, such as epoxy molding compounds and organic molding compounds, are commonly used with fan-out (FO) wafer level packaging (WLP) or package-on-packages (PoPs). However, some semiconductor chips may need additional packaging considerations that may pose challenges for conventional molding compound-based FO processes. For example, some semiconductor chips may need increased thermal management and grounding configurations that require thermal and electrical connection to a bottom (encapsulated) side of the semiconductor chip. Compound semiconductor chips that operate at the extremely high frequency (EHF) or mmWave band (e.g., >28 GHz) may need these additional packaging considerations.

Accordingly, a need exists for integrated circuit packages configured to accommodate compound semiconductor chips that operate at the EHF or mmWave band. This need and other needs are addressed by the glass-based integrated circuit packages and corresponding FO processes disclosed herein.

### SUMMARY

One or more aspects of the present disclosure are directed to an integrated circuit package. The integrated circuit package includes a glass substrate with a glass cladding layer fused to a glass core layer. A cavity is formed in the glass substrate. The cavity has a floor defined by the glass core layer and a sidewall defined by the glass cladding layer. The integrated circuit package further includes a metal layer configured to define a continuous path of thermally and electrically conductive material. The metal layer is disposed within the cavity and along a first surface of the glass cladding layer. The first surface faces opposite an interface between the glass core layer and the glass cladding layer. The integrated circuit package further includes an integrated circuit chip that is disposed within the cavity. The integrated circuit chip contacts a portion of the metal layer within the cavity. The metal layer is configured to provide thermal and electrical connection to a bottom (encapsulated) side of the integrated circuit chip.

### BRIEF DESCRIPTION OF THE DRAWINGS

FIG. 1 is a schematic cross-sectional view of a glass substrate according to embodiments;

FIG. 2 is a schematic cross-sectional view of the glass substrate of FIG. 1 during exposure to an etchant through a mask to form a plurality of cavities in a glass cladding layer according to embodiments;

FIG. 3 is a schematic cross-sectional view of the glass substrate of FIG. 2 after the cavities are formed and the mask is removed according to embodiments;

FIG. 4A is a top perspective view of the glass substrate of FIG. 3;

FIG. 4B is a top perspective view of a portion of the glass substrate of FIG. 4A enlarged to illustrate features of a cavity representative of the plurality of cavities;

FIG. 4C is a schematic cross-sectional view of the glass substrate of FIG. 4B along line A-A showing the cavity prior to deposition of a metal layer;

FIG. 5A is a top perspective view of the glass substrate of FIG. 4B after the metal layer is deposited according to a first configuration;

FIG. 5B is a schematic cross-sectional view of the glass substrate of FIG. 5A along line A-A showing the metal layer in the first configuration;

FIG. 6 is a top perspective view of the glass substrate of FIG. 4B after the metal layer is deposited according to a second configuration;

FIG. 7 is a top perspective view of the glass substrate of FIG. 4B after the metal layer is deposited according to a third configuration;

FIG. 8A is a top perspective view of the glass substrate of FIG. 4B after the metal layer is deposited according to a fourth configuration;

FIG. 8B is a schematic cross-sectional view of the glass substrate of FIG. 8A along line D-D showing the metal layer in the fourth configuration;

FIG. 9A is a top perspective view of the glass substrate of FIG. 4B after the metal layer is deposited according to a fifth configuration;

FIG. 9B is a schematic cross-sectional view of the glass substrate of FIG. 9A along line E-E showing the metal layer in the fifth configuration;

FIG. 10 is a schematic cross-sectional view of an integrated circuit package comprising a glass substrate with a metal layer deposited in a cavity thereof and an integrated circuit chip positioned in the cavity, the metal layer thermally and electrically connected to at least one contact on a side surface of the integrated circuit package; and

FIG. 11 is a schematic cross-sectional view of an integrated circuit package comprising a glass substrate with a metal layer deposited in a cavity thereof and an integrated circuit chip positioned in the cavity, the metal layer thermally and electrically connected to at least one contact on a top surface of the integrated circuit package.

### DETAILED DESCRIPTION

For the purposes of promoting an understanding of the principles of the disclosure, reference will now be made to the embodiments illustrated in the drawings and described in the following written specification. It is understood that no limitation to the scope of the disclosure is thereby intended. It is further understood that the present disclosure includes any alterations and modifications to the illustrated embodiments and includes further applications of the principles disclosed herein as would normally occur to one skilled in the art to which this disclosure pertains

As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

In this document, relational terms, such as first and second, top and bottom, and the like, are used solely to distinguish one entity or action from another entity or action, without necessarily requiring or implying any actual such relationship or order between such entities or actions.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” It will be further understood that the end-points of each of the ranges are significant both in relation to the other end-point, and independently of the other end-point.

The terms “substantial,” “substantially,” and variations thereof as used herein, unless defined elsewhere in association with specific terms or phrases, are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

Directional terms as used herein—for example up, down, right, left, front, back, top, bottom, above, below, and the like—are made only with reference to the figures as drawn and are not intended to imply absolute orientation.

As used herein the terms “the,” “a,” or “an,” mean “at least one,” and should not be limited to “only one” unless explicitly indicated to the contrary. Thus, for example, reference to “a component” includes embodiments having two or more such components unless the context clearly indicates otherwise.

Integrated circuit (IC) packaging is the back-end process of semiconductor device fabrication, in which the block of semiconducting material is packaged in a supporting case that provides an electrical connection from the chip density to the printed circuit board density and prevents physical damage and corrosion to the semiconducting material. The case, known as a “package,” supports the electrical contacts which connect the device to a circuit board. This process is often referred to as packaging, but also can be referred to as semiconductor device assembly, encapsulation, or scaling.

Wafer-level packaging or wafer-level chip-scale packaging (WLP) is the technology of packaging an IC (e.g., chips or dies) while still part of the wafer, in contrast to the more conventional method of slicing the wafer into individual circuits (dicing) and then packaging them. WLP can enable integration of wafer fabrication, packaging, testing, and burn-in at the wafer-level to streamline the manufacturing process undergone by a device from silicon start to customer shipment. WLP can include extending the wafer fabrication processes to include device interconnection and device protection processes. Most other kinds of packaging processes do wafer dicing first, and then put the individual die in a plastic package and attach the solder bumps. WLP involves attaching the top and bottom outer layers of packaging and the solder bumps to ICs while still in the wafer and then dicing the wafer.

One type of WLP is fan-in (FI), which has all the contact terminals within the footprint of the die. Such a configuration can pose a significant limitation when adjusting the layout of the contact terminals to match the design of the next-level substrate. Fan-out (FO) is another type of WLP that represents a compromise between die-level packaging and FI WLP. FO WLP involves dicing the semiconductor wafer and then embedding the singularized ICs in a reconstituted or artificial molded wafer. The dies are separated from each other on the reconstituted wafer by a distance that is large enough to allow the desired FO redistribution layer (RDL) to be manufactured using standard WLP processes. FO WLP provides a way to connect the smaller die with fine lead pitch to the larger lead pitch of a printed circuit board.

Molding compounds, such as epoxy molding compounds and organic molding compounds, are commonly used with fan-out (FO) wafer level packaging (WLP) (e.g., FO WLP). However, some packaging configurations may pose challenges for such molding compound-based FO processes. For example, some semiconductor chips may require increased thermal management and grounding configurations that require thermal and electrical connection to a bottom (encapsulated) side of the semiconductor chip. The glass-based integrated circuit packages and corresponding FO processes disclosed herein address these and other challenges.

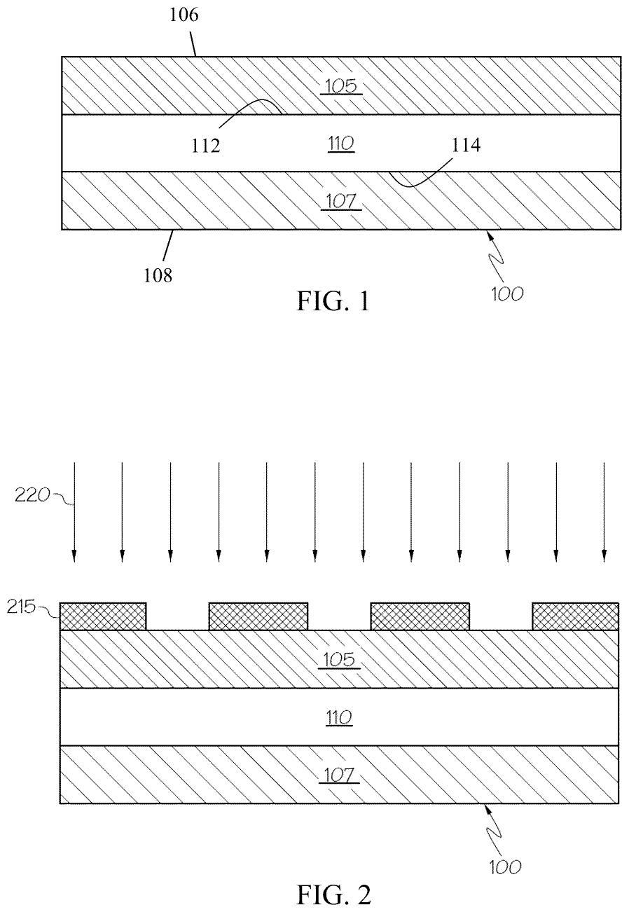

FIG. 1 is a schematic cross-sectional view of a glass substrate 100 according to embodiments. The glass substrate 100 includes a glass core layer 110 disposed between a first or upper glass cladding layer 105 and a second or lower glass cladding layer 107. The glass substrate 100 includes multiple glass-based layers and can be considered a glass laminate. In embodiments, the first glass cladding layer 105 and/or the second glass cladding layer 107 can be exterior layers relative to the glass core layer 110. For example, the first glass cladding layer 105 can define an outer or first surface 106 of the glass substrate 100 and/or the second glass cladding layer 107 can define an outer or second surface 108 of the glass substrate 100, as shown in FIG. 1.

The glass core layer 110 comprises a first major surface and a second major surface opposite the first major surface. In embodiments, the first glass cladding layer 105 is fused to the first major surface of the glass core layer 110, and the second glass cladding layer 107 is fused to the second major surface of the glass core layer 110. In such embodiments, an interface 112 (e.g., a first interface) between the first glass cladding layer 105 and the glass core layer 110 and/or an interface 114 (e.g., a second interface) between the second glass cladding layer 107 and the glass core layer 110 are free of any bonding material such as, for example, an adhesive, a coating layer, or any non-glass material added or configured to adhere the respective cladding layers to the core layer.

In embodiments with such interfaces 112, 114, the first glass cladding layer 105 and/or the second glass cladding layer 107 are fused directly to the glass core layer 110 and/or are directly adjacent to the glass core layer 110. The first surface 108 faces opposite the first interface 112, and the second surface 108 faces opposite the second interface 114. The first surface 106 may be referred to as a first major surface, and the second surface 108 may be referred to as a second major surface since the first and second glass cladding layers 105, 107 are fused to the first and second major surfaces, respectively, of the glass core layer 110. In other embodiments, the layers 105, 107, 110 can be coupled (e.g., adhered) together using adhesives or the like.

The glass substrate 100 can have any suitable composition and be made using any suitable method. Examples of suitable glass compositions can include alkaline-earth aluminoborosilicate glasses, zinc borosilicate glasses, and soda-lime glass as well as glass ceramics, such as those enriched with magnesium oxide, yttria, beryllia, alumina, or zirconia. In general, the glass substrate 100 and any of the layers 105, 107, 110 in the glass substrate can have any of the compositions or be made using any of the methods disclosed in U.S. Pat. No. 9,340,451 entitled “Machining of Fusion-Drawn Glass Laminate Structures Containing a Photomachinable Layer,” issued May 17, 2016, and U.S. Pat. No. 10,077,208 entitled “Glass Article and Method for Forming the Same,” issued Sep. 18, 2018, each of which is incorporated herein by reference in its entirety.

The glass substrate 100 is configured so that at least one of the glass cladding layers 105, 107 and the glass core layer 110 have different physical dimensions and/or physical properties that allow for selective removal of a portion of the at least one glass cladding layer 105, 107 relative to the glass core layer 110 to form precisely dimensioned cavities 425, which can be sized and shaped to receive microelectronic components, for example.

An aspect of the glass substrate 100 that can vary widely is the thickness of the layers 105, 107, 110. For example, the layers 105, 107, 110 can all have the same thickness or different thicknesses or two of the layers can be the same thickness while the third layer has a different thickness. In embodiments, one or both of the glass cladding layers 105, 107 may have a thickness that is the same or substantially the same as the thickness of a microelectronic component configured to be packaged in the glass substrate 100.

In embodiments, one or both of the glass cladding layers 105, 107 are approximately 70 μm to approximately 400 μm thick or approximately 100 μm to approximately 300 μm thick. In embodiments, one or both of the cladding layers 105, 107 are at least approximately 70 μm thick or at least approximately 100 μm thick. In embodiments, one or both of the cladding layers 105, 107 are no more than 400 μm thick or no more than 300 μm thick. These thicknesses generally correspond to the thickness of microelectronic components that commonly undergo FO WLP processing. It should be appreciated, however, that the glass cladding layers 105, 107 can have other thicknesses, particularly, when used with microelectronic components having smaller or larger thicknesses than those described herein.

Another aspect of the glass substrate 100 that can vary widely is the glass composition of the layers 105, 107, 110. For example, the layers 105, 107, 110 can all have the same glass composition or different glass compositions or two of the layers can have the same glass composition while the third layer has a different glass composition. In general, one or both of the glass cladding layers 105, 107 have a glass composition that is different than the glass composition of the glass core layer 110. This difference provides the glass cladding layers 105, 107 certain properties that make them suitable to the formation of the cavities 425.

In embodiments, the glass compositions of the layers 105, 107, 110 can vary such that the durability of the layers 105, 107, 110 in an etchant varies. For example, in embodiments, one or both of the glass cladding layers 105, 107 can have a dissolution rate in the etchant that is different than the glass core layer 110. The different durability between the layers 105, 107, 110 makes it possible to form the cavities 425 in the surface of the glass substrate 100. For example, the glass cladding layers 105, 107 can have a sufficiently high dissolution rate in the etchant that they can be etched to form the cavities 425. On the other hand, the glass core layer 110 can have a sufficiently low dissolution rate in the etchant that it is not substantially susceptible to being etched. Thus, the glass core layer 110 can act as an etch stop to limit the depth to which the glass substrate 100 can be etched using the etchant.

In embodiments, one or both of the glass cladding layers 105, 107 have a dissolution rate in the etchant that is greater than the dissolution rate of the glass core layer 110. For example, the glass core layer 110 can have a dissolution rate in the etchant that is zero or sufficiently close to zero that it is insusceptible to being etched to any significant extent.

In embodiments, the glass compositions of the layers 105, 107, 110 can vary such that the photosensitivity of the layers 105, 107, 110 varies. For example, in embodiments, one or both of the glass cladding layers 105, 107 can have a photosensitivity that is different than the glass core layer 110. The different photosensitivity between the layers 105, 107, 110 makes it possible to form the cavities 425 in the surface of the glass substrate 100. For example, the glass cladding layers 105, 107 can be sufficiently photosensitive that they can be photomachined to form the cavities 425. For example, exposure of the glass cladding layers 105, 107 to a radiation source can alter the properties of the glass cladding layer 105, 107. On the other hand, the glass core layer 110 can be sufficiently non-photosensitive that it is not susceptible to being photomachined. For example, the properties of the glass core layer 110 can be substantially unaffected by exposure to the radiation source.

In embodiments, one or both of the glass cladding layers 105, 107 have a photosensitivity that is greater than the photosensitivity of the glass core layer 110. For example, the glass core layer 110 can have a photosensitivity that is zero or sufficiently close to zero that it is not susceptible to being photomachined to any significant extent.

It should be appreciated that numerous changes can be made to the embodiments of the glass substrate 100 shown in FIG. 1. For example, in some embodiments, the glass substrate 100 can include only two glass layers 105, 110. In other embodiments, the glass substrate 100 can include four or more glass layers. Numerous other variations are also contemplated.

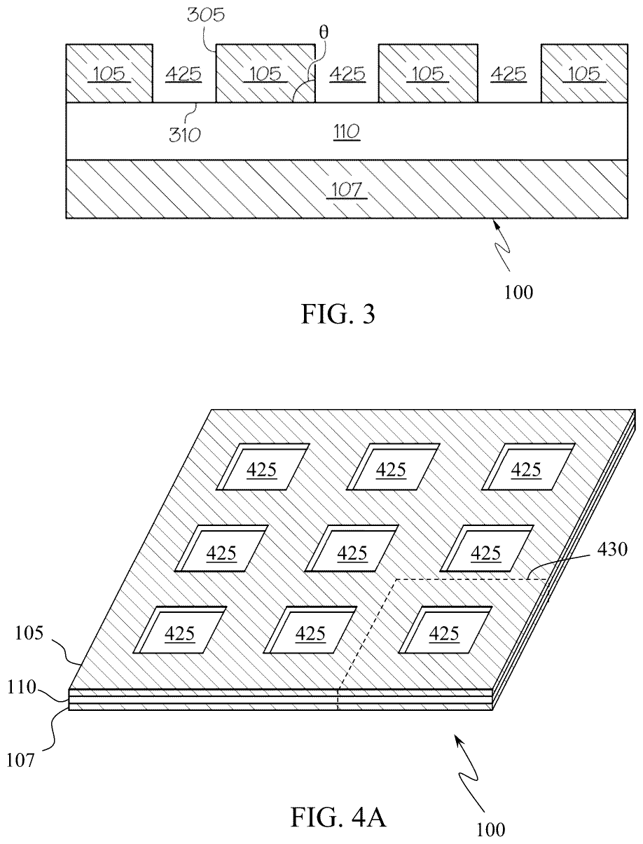

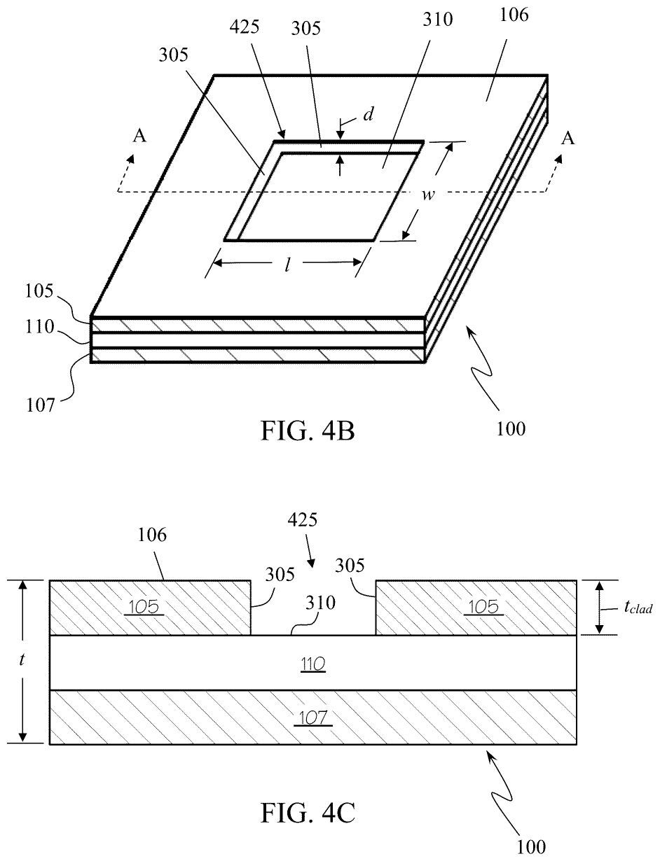

In embodiments, cavities 425 (FIGS. 3, 4A, 4B) are formed in the glass substrate 100 to transform the glass substrate into a structured article as described herein. The cavities 425 can be formed in the surface of the glass substrate 100 using the method depicted in FIG. 2. In embodiments, the method includes forming a mask 215 on a surface (e.g., the first surface 106) of the glass substrate 100. For example, the mask 215 is formed on the surface of the glass cladding layer 105 and/or the glass cladding layer 107. The mask 215 can be formed by printing (e.g., inkjet printing, gravure printing, screen printing, or another printing process) or another deposition process. In embodiments, the mask 215 is resistant to the etchant (e.g., the etchant that will be used to etch the cavities 425 in the glass substrate 100). For example, the mask 215 can include an acrylic ester, a multifunctional acrylate n vinylcaprolactam, or another suitable mask material. In embodiments, the mask 215 is formed from an ink material comprising a primer to enhance adhesion between the mask and the glass substrate 100. Such enhanced adhesion can reduce seepage of the etchant between the mask 215 and the glass substrate 100, which can help to enable the precise cavities 425 described herein.

In embodiments, the mask 215 includes one or more open regions at which the glass substrate 100 remains uncovered. The open regions of the mask 215 can have a pattern corresponding to the desired pattern of the cavities to be formed in the glass substrate 100. For example, the pattern of the mask 215 can be an array of regularly repeating rectangular shapes (e.g., to receive microelectronic components as described herein). In such embodiments, the shapes patterned by the mask 215 can correspond closely to the shape of the microelectronic components. Other shapes can also be used, and the shapes can correspond closely to the shape of the microelectronic component or be capable of securely holding the microelectronic component in position on the glass substrate 100. Thus, the mask 215 can be configured as an etch mask to enable selective etching of the glass cladding layer 105 and/or the glass cladding layer 107 and form the cavities 425 in the glass substrate 100, as described herein.

In embodiments, the glass substrate 100 with the mask 215 disposed thereon is exposed to the etchant 220. For example, the glass cladding layer 105 and/or the glass cladding layer 107 is contacted with the etchant 220 as shown in FIG. 2, thereby selectively etching an exposed portion of the respective glass cladding layer that is uncovered by the mask 215 and forming the cavities 425 in the glass substrate, thereby transforming the substrate into the shaped article. Thus, following formation of the cavities 425, the glass substrate 100 can be referred to as the (precision) shaped article.

In embodiments, the glass substrate 100 with the mask 215 disposed thereon is exposed to the etchant 220 at an etching temperature and for an etching time. For example, the etching temperature is about 20° C., about 22° C., about 25° C., about 30° C., about 35° C., about 40° C., about 45° C., or about 50° C., or any ranges defined by any combination of the stated values. A lower etching temperature can help to maintain the integrity of the mask 215 during the etching, which can enable an increased etching time and/or improved cavity shape as described herein.

Additionally, or alternatively, the etching time can be about 10 minutes, about 15 minutes, about 20 minutes, about 25 minutes, about 30 minutes, about 35 minutes, about 40 minutes, about 45 minutes, about 50 minutes, about 55 minutes, about 60 minutes, about 65 minutes, about 70 minutes, about 75 minutes, about 80 minutes, about 85 minutes, or about 90 minutes, or any ranges defined by any combination of the stated values. A relatively long etching time (e.g., an etching time of greater than 10 minutes) can enable substantially vertical sidewalls of the cavities 425, as described herein.

In embodiments, the glass cladding layer 105 and/or the glass cladding layer 107 etch at least 1.5 times faster, at least 2 times faster, at least 5 times faster, at least 10 times faster, at least 20 times faster, or at least 100 times faster than the glass core layer 110. Additionally, or alternatively, a ratio of the etch rate of the glass cladding layer 105 and/or the glass cladding layer 107 to the etch rate of the glass core layer 110 is about 5, about 10, about 15, about 20, about 25, about 30, about 35, about 40, about 45, about 50, about 55, about 60, about 65, about 70, about 75, about 80, about 85, about 90, about 95, about 100, or any ranges defined by any combination of the stated values.

In embodiments, forming the cavities 425 includes etching substantially entirely through the glass cladding layer 105 and/or the glass cladding layer 107 to expose a portion of the glass core layer 110 at the bottom of the cavities, as shown in FIG. 3. Thus, the sidewalls 305 of the cavities 425 are defined by the glass cladding layer 105 and/or the glass cladding layer 107, and the floors 310 of the cavities are defined by the glass core layer 110. In embodiments, the glass core layer 110 is not substantially etched during the forming the cavities 425. Thus, the glass core layer 110 serves as an etch stop that determines the depth of the cavities 425.

In embodiments, the floor 310 of each of the cavities 425 is of optical quality. For example, a surface roughness (Ra) of the floor 310 of each of the cavities 425 is at most about 50 nm, at most about 40 nm, at most about 30 nm, at most about 20 nm, at most about 10 nm, at most about 9 nm, at most about 8 nm, at most about 7 nm, at most about 6 nm, or at most about 5 nm. Such low surface roughness can be enabled by the etch stop provided by the glass core layer 110 and/or agitating the etchant during the etching to remove etching byproducts from each of the cavities 425. Additionally, or alternatively, such low surface roughness can enable light to pass through the floor 310 (e.g., for optical activation and/or analysis of an object or material disposed within the cavities) without substantial distortion.

In embodiments, the floor 310 of each of the cavities 425 is substantially flat. For example, a difference between a first depth of the cavity 425 at a first position along the perimeter of the cavity 425 and a second depth of the cavity 425 at a second position along the perimeter of the cavity 425 opposite the first position (e.g., diametrically opposed) is at most about 5 μm, at most about 4 μm, at most about 3 μm, at most about 2 μm, at most about 1 μm, at most about 0.9 μm, at most about 0.8 μm, at most about 0.7 μm, at most about 0.6 μm, at most about 0.5 μm, at most about 0.4 μm, at most about 0.3 μm, at most about 0.2 μm, or at most about 0.1 μm. Such a low depth difference can be enabled by the etch stop provided by the glass core layer 110. For example, the depth of the cavity 425 can be determined primarily by the thickness t of the glass cladding layer 105 and/or the glass cladding layer 107 without changing substantially as a result of changes in etch temperature and/or etch time.

In embodiments, the sidewalls 305 of the cavities 425 are substantially vertical. For example, an angle θ formed between the sidewall 305 and the floor 310 of the cavity 425 measured within the glass cladding is approximately 90°, or from about 85° to about 91°. In embodiments, the angle θ formed between the sidewall 305 and the floor 310 of the cavity 425 measured within the glass gladding (shown in FIG. 3) can be from about 60° to about 90°. In some of such embodiments, the depth of the cavity is at least about 30 μm, at least about 40 μm, at least about 50 μm, at least about 60 μm, at least about 70 μm, at least about 80 μm, or at least about 90 μm. For example, the depth of the cavity can be from about 30 μm to about 210 μm, from about 40 μm to about 200 μm, from about 50 μm to about 150 μm. Such a low angle of the sidewalls can be enabled by an increased etching time, which can be enabled by the etch stop provided by the glass core layer 110. For example, the etching time can be extended to remove material at the intersection between the sidewalls and the floor near the bottom of the cavity without substantially increasing the depth of the cavity. Removing such material can result in a straighter (e.g., vertical) sidewall compared to conventional wet etching processes.

In embodiments, after forming the cavities 425, the mask 215 is removed from the glass substrate 100. For example, removing the mask 215 includes contacting the mask with a solvent, thereby removing the mask from the surface of the glass substrate 100. In embodiments, the solvent is water. For example, removing the mask 215 includes submerging the glass substrate 100 with the mask 215 disposed thereon into water, thereby removing the mask from the surface of the glass substrate.

FIG. 3 and FIG. 4 are schematic cross-sectional and perspective views, respectively, of the glass substrate 100 with the cavities 425 formed therein and the mask 215 removed therefrom. Additional details on the formation of cavities 425 within the glass substrate 100 may be found in U.S. Pat. No. 11,367,665 entitled “Precision Structured Glass Articles, Integrated Circuit Packages, Optical Devices, Microfluidic Devices, and Methods for Making the Same,” issued Jun. 21, 2022, which is incorporated herein by reference in its entirety.

Although embodiments are described herein with reference to using an etching process to form the cavities 425 in the glass substrate 100, it is contemplated that in some embodiments, the cavities 425 may be formed in the glass substrate 100 by a photomachining process. For example, a photomask may be applied to the first surface 106 of the first glass cladding layer 105. The first glass cladding layer 105 may then be exposed to a source of radiation through the photomask to pattern the cavities 425. Any suitable source of radiation can be used in the photomachining process, provided that it is capable of altering the properties of the first glass cladding layer 105. For example, the source of radiation can be a UV lamp. In embodiments, the first glass cladding layer 105 is sufficiently photosensitive that the radiation changes its crystallinity properties, forming crystallized regions that are capable of being selectively removed by a physical and/or chemical procedure such as selective etching (e.g., wet etching). Details on such a process may be found U.S. Pat. No. 11,367,665, referenced in the immediately prior paragraph.

Referring now to FIG. 4B, a portion of the glass substrate 100, such as the portion indicated by dashed line 430 in FIG. 4A, is enlarged to illustrate features of a (single) cavity 425 formed in the glass substrate 100. FIG. 4C is a schematic cross-sectional view of the portion of the glass substrate 100 along line A-A in FIG. 4B to further illustrate features of the cavity 425. The features depicted in FIG. 4B and FIG. 4C are representative of the features of the plurality of cavities 425 formed via the processes described above.

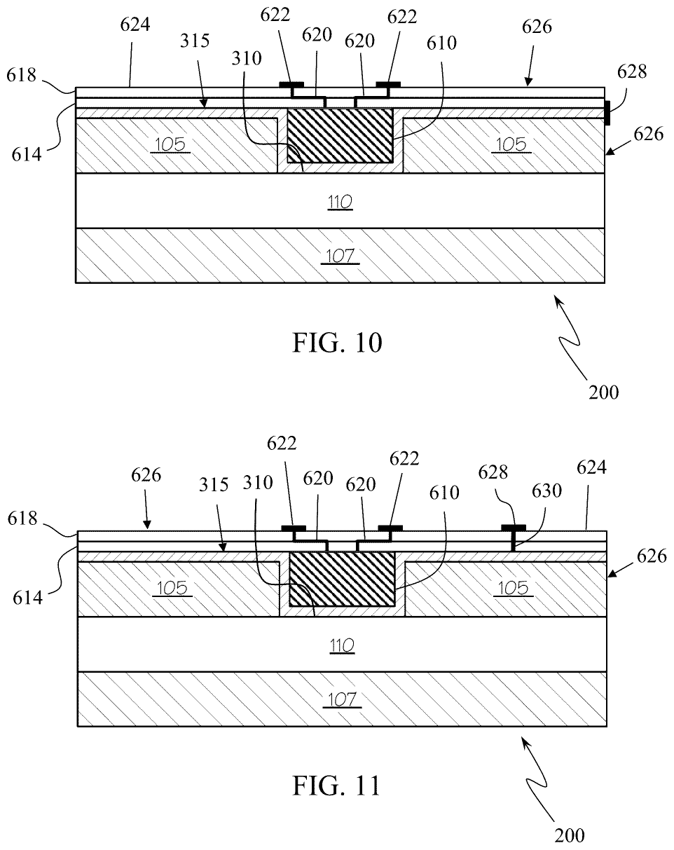

As shown in FIG. 4B and FIG. 4C, the cavity 425 has a rectangular shape that substantially corresponds to the shape of the microelectronic components 610 (FIG. 10 and FIG. 11) to be positioned in the cavities. The cavity 425 has a length l measured in a first direction substantially parallel to the first surface 106 of the first glass cladding layer 105. The cavity 425 has a width w measured in a second direction substantially parallel to the first surface 106 and substantially normal to the first direction along which the length l is measured. The cavity 425 has a depth d measured in a third direction substantially normal to the first surface 106. The third direction also corresponds generally to the thickness t of the glass substrate 100 and the layers 105, 107, 110 thereof. The depth d of the cavity 425 can be determined primarily by the thickness f_{clad} of the first glass cladding layer 105 when the compositions of the layer 105, 107, 110 are configured with the different dissolution rates and/or photosensitivities, as previously described herein.

While the cavities shown in FIGS. 4A-4C are depicted having a rectangular shape, it should be appreciated that the cavities 425 can have any suitable shape, and such shape can vary depending on the particular microelectronic component to be positioned therein. For example, the cavities 425 can have a square shape, a circular shape, or any other polygonal or non-polygonal shape.

The glass substrate 100 with the cavities 425 formed therein can be further configured to accommodate microelectronic components with features that are challenging to package using conventional mold compound-based FO WLP. For example, in embodiments, the microelectronic components are compound semiconductor chips configured to operate at extremely high frequencies referred to as millimeter wave or mmWave. This band of the spectrum has wavelengths between 10 mm (at approximately 28 to 30 GHz) and 1 mm (at approximately 300 GHz). This band is also referred to as the extremely high frequency (EHF) band.

Integrated circuit (IC) chips configured to operate at mmWave may generate more heat than IC chips that operate at frequencies below mmWave. Additionally, IC chips configured to operate at mmWave may have different electrical grounding configurations than IC chips that operate at frequencies below mmWave. For example, mmWave IC chips may have ground contacts located on surfaces opposite (or different) from the surface(s) on which the main input/output (I/O) electrical contacts are located. Accordingly, packaging structures and design processes that incorporate mmWave IC chips must account for these thermal and grounding needs.

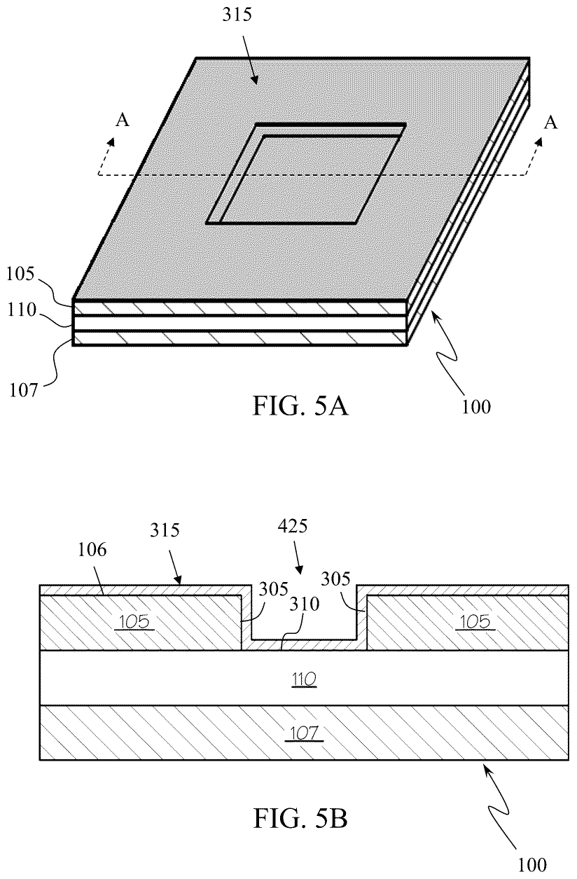

Referring now to FIGS. 5A, 5B, 6, 7, 8A, 8B, 9A, 9B, the glass substrate 100 is shown with a metal layer 315 deposited thereon (and optionally patterned) in different configurations to accommodate IC chips configured to operate at mmWave. In FIGS. 5A, 6, 7, 8A, and 9A, the metal layer 315 is indicated by the use of gray shading added to the surfaces of the glass substrate 100 on which the metal layer 315 is deposited (e.g., first surface 106, sidewall 305, floor 310) in the specified configuration. Reference can be made to FIG. 4B for a depiction of the corresponding surfaces of the glass substrate 100 before the metal layer 315 is deposited thereon. It should be appreciated that the specific configurations disclosed herein are exemplary and various other configurations of the metal layer 315 are contemplated.

In each configuration shown and contemplated, the metal layer 315 is disposed (at least partially) within the cavity 425 and (at least partially) along the first surface 106 of the first glass cladding layer 105. In embodiments in which cavities are additionally, or alternatively, formed in the second glass cladding layer 107, the metal layer 315 can also be disposed within those cavities and along the second surface 108 of the second glass cladding layer 107. For simplicity, the various configurations of the metal layer 315 are described with reference to the cavities 425 formed in the first glass cladding layer 105.

In each configuration shown and contemplated, the metal layer 315 comprises a thermally and electrically conductive material. In embodiments, the thermally and electrically conductive material is aluminum, copper, graphene, titanium, or combinations thereof. Similarly, in embodiments, the metal layer 315 comprises a layer of aluminum, a layer of copper, a layer of graphene, a layer of titanium, or a combination thereof. In exemplary embodiments, the metal layer 315 comprises a layer of copper, which may be well suited in terms of properties and processing to accommodate IC chips configured to operate at mmWave. In such exemplary embodiments, the layer of copper can include additional material or additives such as graphene and/or carbon to further improve the heat dissipation performance of the metal layer 315.

In each configuration shown and contemplated, the metal layer 315 is configured to define a continuous path of the thermally and electrically conductive material. In embodiments, the continuous path of the thermally and electrically conductive material extends within the cavity 425 (e.g., along the surfaces of the glass core layer 110 and the first glass cladding layer 105 that define the cavity), passes through the opening to the cavity 425 in the first surface 106 of the first glass cladding layer 105, and extends along at least a portion of the first surface 106. As used herein, the term “continuous path” means the thermally and electrically conductive material extends without interruption or discontinuity along the indicated surfaces or portions of the indicated surfaces. The continuous path enables heat and electricity (e.g., electrical current and/or signals) from structures disposed within the cavity 425, such as the IC chips 610 in FIG. 10 and FIG. 11, to be conducted continuously along the metal layer 315 to external surfaces of the glass substrate 100 and/or external surfaces an integrated circuit package within which the glass substrate 100 and the IC chips 610 are packaged.

The metal layer 315 can be deposited according to any suitable method. Suitable methods include, by way of example and not limitation, sputtering, plating, or the like. In embodiments, the metal layer 315 can be patterned after deposition according to any suitable method. In embodiments, the metal layer 315 can be patterned not only to form thermal/electrical interconnects, but also to form passive devices such as capacitors or inductors (e.g., sometimes referred to as integrated passive devices) since the glass substrate 100 is sufficiently chemically durable to undergo a photolithography process. In some embodiments, the configuration of the metal layer 315 is achieved by the deposition method alone. In other embodiments, the configuration of the metal layer 315 is achieved by a combination of deposition and patterning methods. The method(s) can vary depending on the particular embodiment and/or configuration.

The material(s) used with existing FO processes (e.g., epoxy mold compound) do not allowed for depositing a metal layer, such as the metal layer 315 disclosed herein, for grounding contact and thermal heat dissipation. More specifically, the metal deposition step cannot be incorporated in the process flow in which a mold compound directly encapsulates the IC chips, and the polymer material is not compatible with the high temperature sputter process associate with embodiments of the metal deposition.

In embodiments, the metal layer 315 has a thickness that depends on the particular application. For integrated circuit packages with IC chips configured to operate at mmWave frequencies, the thickness of the metal layer 315 can be based on (e.g., a function of) a driving power of the IC chip since higher driving power may correspond with higher heat generation. In other words, the driving power of the IC chip may influence the heat dissipation strategy needed for the integrated circuit package configured to accommodate that IC chip. In general, increasing the thickness of the metal layer 315 increases heat dissipation capacity (i.e., the heat dissipation rate) along the metal layer 315. Thus, in embodiments, the thickness of the metal layer 315 (in millimeters) can be in a range of from 8 to 12 times (e.g., from 7 to 13 times, or from 9 to 11 times, or from 8 to 11 times, or from 9 to 12 times) the driving power (in Watts) of the integrated circuit chip to be positioned in the cavity 425.

The driving power or power of the IC chip 610 may refer to the average power of the IC chip. The driving power in embodiments may relate to the power need to drive the IC chip at its operating frequency. In embodiments, the IC chips 610 are configured to operate at mmWave frequencies, such as an operating frequency in a range of from about 25 GHz to about 300 GHz, or from equal to or greater than 28 GHz, such as from about 28 GHz to about 300 GHz, and also comprising all sub-ranges and sub-values between these range endpoints.

In embodiments, the power of the IC chip 610 can be in a range of from about 0.1 W to about 5 W, or from about 0.25 W to about 2 W, or from about 0.5 W to about 1 W, or from about 0.1 W to about 2 W, or from about 0.1 W to about 1 W, or from about 0.25 W to about 5 W, or from about 0.25 W to about 1 W, or from about 0.25 W to about 0.75 W, and also comprising all sub-ranges and sub-values between these range endpoints.

In embodiments, the thickness of the metal layer 315 is in a range of from about 1 μm to about 20 μm, or from about 1.5 μm to about 18 μm, or from about 2 μm to about 16 μm, or from about 2.5 μm to about 14 μm, or from about 3 μm to about 12 μm, or from about 3.5 μm to about 10 μm, or from about 4 μm to about 8 μm, or from about 4.5 μm to about 6 μm, or from about 5 μm to about 10 μm, or from about 1 μm to about 16 μm, or from about 1 μm to about 10 μm, or from about 1 μm to about 4 μm, or from about 3 μm to about 20 μm, or from about 6 μm to about 20 μm, or from about 9 μm to about 20 μm, and also comprising all sub-ranges and sub-values between these range endpoints.

Referring now to FIG. 5A and FIG. 5B, the glass substrate 100 is shown with the metal layer 315 deposited according to a first configuration. In the first configuration, the metal layer 315 is disposed on an entirety of the first surface 106 of the first glass cladding layer 105. In the first configuration, the metal layer 315 is disposed on an entirety of the sidewall 305 of the cavity 425. In the first configuration, the metal layer 315 is disposed on an entirety of the floor 310 of the cavity 425. As shown, the thermally and electrically conductive material (e.g., gray shading) extends without interruption or discontinuity along an entirety of each of the first surface 106, the sidewalls 305, and the floor 310 such that the metal layer 315 defines the continuous path of the thermally and electrically conductive material.

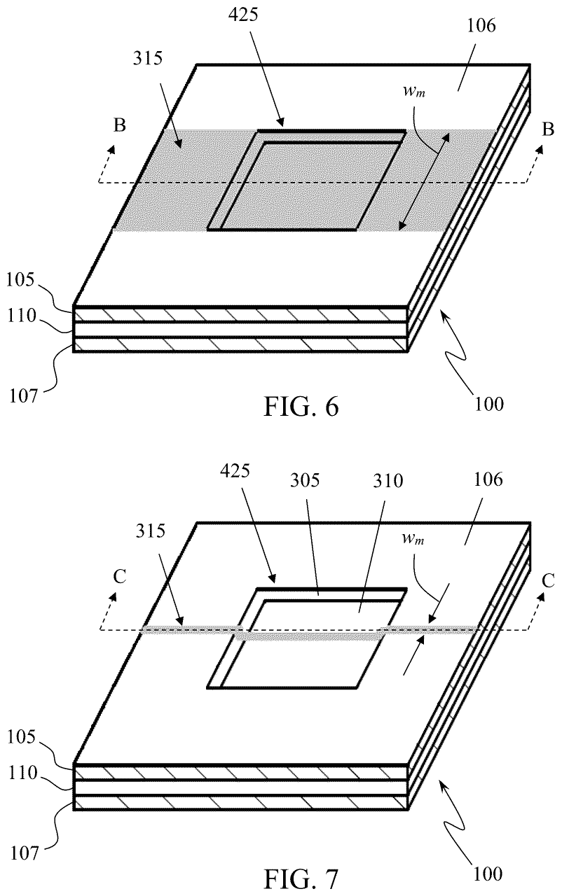

Referring now to FIG. 6, the glass substrate 100 is shown with the metal layer 315 deposited according to a second configuration. In the second configuration, the metal layer 315 is disposed on a portion of the first surface 106 of the first glass cladding layer 105. In the second configuration, the metal layer 315 is disposed on an entirety of the sidewall 305 of the cavity 425. In the second configuration, the metal layer 315 is disposed on an entirety of the floor 310 of the cavity 425. The metal layer 315 disposed on the first surface 106 is configured as a swath of the thermally and electrically conductive material that extends bilaterally from the cavity 425 to sides of the glass substrate 100 in a direction corresponding to the direction in which the length l of the cavity 425 is measured (e.g., direction of length l in FIG. 4B). The swath of the thermally and electrically conductive material has a width wₘ that corresponds in direction and measurement to the width w of the cavity 425 (e.g., direction and measurement of width w in FIG. 4B).

As shown, the thermally and electrically conductive material (e.g., gray shading) extends without interruption or discontinuity along an entirety of each of the sidewalls 305 and the floor 310, and along the swath that extends entirely across the first surface 106 such that the metal layer 315 defines the continuous path of the thermally and electrically conductive material. A cross section of the glass substrate 100 taken along line B-B in FIG. 6 has the same configuration as the cross section shown in FIG. 5B. However, if line B-B in FIG. 6 was rotated 90 degrees about its midpoint, the cross section of glass substrate 100 of FIG. 6 would not show the metal layer 315 disposed on the first surface 106 due to the configuration of the metal layer 315 as described in the second configuration.

Referring now to FIG. 7, the glass substrate 100 is shown with the metal layer 315 deposited according to a third configuration. In the third configuration, the metal layer 315 is disposed on a portion of the first surface 106 of the first glass cladding layer 105. In the third configuration, the metal layer 315 is disposed on a portion of the sidewall 305 of the cavity 425. In the third configuration, the metal layer 315 is disposed on a portion of the floor 310 of the cavity 425. The metal layer 315 disposed on the glass substrate 100 is configured as a trace of the thermally and electrically conductive material that extends across the first surface 106, the sidewall 305, and the floor 310 in a direction corresponding to the direction in which the length l of the cavity 425 is measured (e.g., direction of length l in FIG. 4B). The trace of the thermally and electrically conductive material has a width wₘ that corresponds in direction to the width w of the cavity 425 (e.g., direction of width w in FIG. 4B). The width wₘ of the trace is less than (e.g., substantially less than) the width w of the cavity 425.

As shown, the thermally and electrically conductive material (e.g., gray shading) extends without interruption or discontinuity along the trace across the first surface 106, the sidewall 305, and the floor 310 such that the metal layer 315 defines the continuous path of the thermally and electrically conductive material. A cross section of the glass substrate 100 taken along line C-C in FIG. 7 has the same configuration as the cross section shown in FIG. 5B. However, if line C-C in FIG. 7 was rotated 90 degrees about its midpoint, the cross section of glass substrate 100 of FIG. 7 would not show the metal layer 315 disposed on the first surface 106 or the sidewall 305 due to the configuration of the metal layer 315 as described in the third configuration. In such a cross section (e.g., with line C-C rotated as described), the metal layer 315 would be disposed centrally along the floor 310.

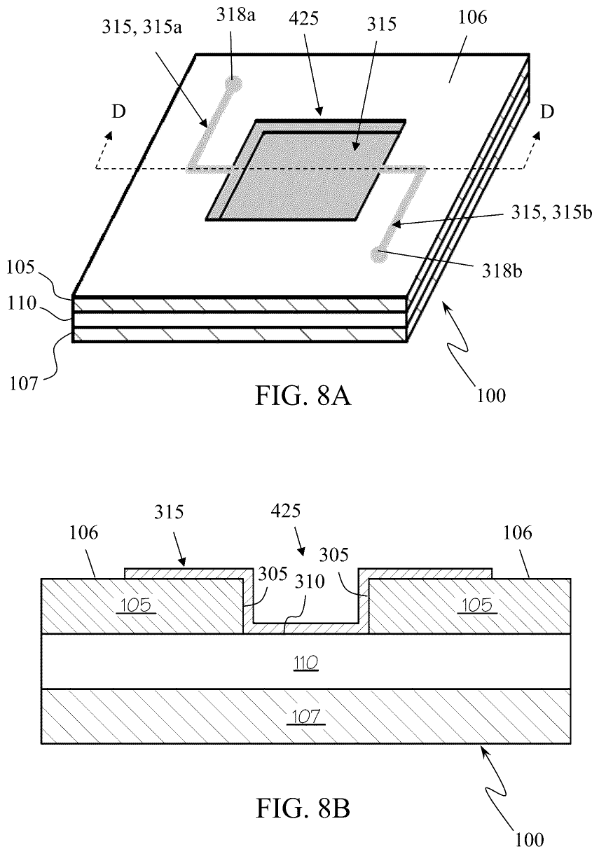

Referring now to FIG. 8A and FIG. 8B, the glass substrate 100 is shown with the metal layer 315 deposited according to a fourth configuration. In the fourth configuration, the metal layer 315 is disposed on a portion of the first surface 106 of the first glass cladding layer 105. In the fourth configuration, the metal layer 315 is disposed on an entirety of the sidewall 305 of the cavity 425. In the fourth configuration, the metal layer 315 is disposed on an entirety of the floor 310 of the cavity 425. The metal layer 315 disposed on the first surface 106 is configured as multiple traces 315a, 315b of the thermally and electrically conductive material that extend, respectively, from opposite sides of the cavity 425 towards sides of the glass substrate 100.

A first trace 315a can extend from one side of the cavity 425 towards a first side of the glass substrate 100. As shown, the first trace 315a does not extend to the first side. Instead, the first trace 315a terminates at a first end 318a prior to the first side. A second trace 315b can extend from another (e.g., opposite) side of the cavity 425 towards a second side of the glass substrate 100 opposite the first side. As shown, the second trace 315b does not extend to the second side. Instead, the second trace 315b terminates at a second end 318b prior to the second side. The first and second traces 315a, 315b of the fourth configuration of the metal layer 315 shown in FIG. 8A can have respective widths that are similar to the width wₘ of the trace 315 of the third configuration of the metal layer 315 shown in FIG. 7.

As shown, the thermally and electrically conductive material (e.g., gray shading) extends without interruption or discontinuity along an entirety of each of the sidewalls 305 and the floor 310, and along the first and second traces 315a, 315b that extend along the first surface 106 such that the metal layer 315 defines the continuous path of the thermally and electrically conductive material. FIG. 8B is a cross section of the glass substrate 100 taken along line D-D in FIG. 8A. As shown in FIG. 8B, the first and second traces 315a, 315b are shown with bends (e.g., 90-degree bends) such that the metal layer 315 shown in the cross section does not extend entirety to the sides of the glass substrate 100. If line D-D in FIG. 8A was rotated 90 degrees about its midpoint, the corresponding cross section of the glass substrate 100 would not show the metal layer 315 disposed on the first surface 106 due to the configuration of the metal layer 315 as described in the fourth configuration.

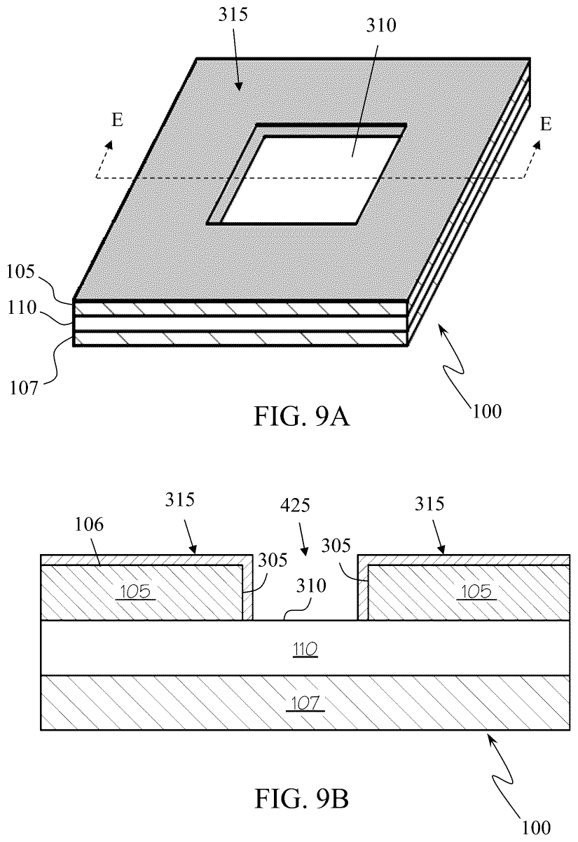

Referring now to FIG. 9A and FIG. 9B, the glass substrate 100 is shown with the metal layer 315 deposited according to a fifth configuration. In the fifth configuration, the metal layer 315 is disposed on an entirety of the first surface 106 of the first glass cladding layer 105. In the fifth configuration, the metal layer 315 is disposed on an entirety of the sidewall 305 of the cavity 425. In the fifth configuration, the metal layer 315 is not present on any portion the floor 310 of the cavity 425. As shown, the thermally and electrically conductive material (e.g., gray shading) extends without interruption or discontinuity along an entirety of each of the first surface 106 and the sidewalls 305 such that the metal layer 315 defines the continuous path of the thermally and electrically conductive material.

Referring now to FIG. 10 and FIG. 11, an integrated circuit package 200 is shown according to embodiments. The integrated circuit package 200 comprises the glass substrate 100 and the metal layer 315 in the various embodiments described throughout this disclosure. The integrated circuit package 200 further comprises the integrated circuit (IC) chip 610 as described throughout this disclosure. In embodiments, the IC chip 610 is a compound semiconductor chip configured to operate at the mm Wave band (e.g., >28 GHz). The IC chip 610 is disposed within the cavity 425 and configured to contact the metal layer 315 within the cavity 425.

Following deposition of the metal layer 315 in the various embodiments disclosed herein, the cavities 425 are each substantially the same size (e.g., length l, width w, and/or depth d) as the IC chips 610 to allow an exact fit of an IC chip 610 in each corresponding cavity 425. In embodiments, it can be desirable for the IC chips 610 to be flush with the first surface 106 of the first glass cladding layer 105 and/or the second surface 108 of the second glass cladding layer 107. In embodiments, it can be desirable for the IC chips 610 to be flush with an upper surface of the metal layer 315 disposed along the first surface 106 of the first glass cladding layer 105 and/or the second surface 108 of the second glass cladding layer 107. Nevertheless, there may be situations where the top of the IC chips 610 may not be perfectly flush with the glass cladding layer(s) 105, 107 and/or the metal layer 315. This condition may be acceptable provided the resulting reconstituted substrate is capable of being further processed to produce the final integrated circuit package 200.

The IC chips 610 can generally vary 1-2 μm in size. In embodiments, the length l, width w, and/or depth d of each cavity 425 including the metal layer 315 varies by no more than 20 μm, no more than 10 μm, no more than 5 μm, or no more than 4 μm relative to: (a) a target size of the dimension(s) of the cavities 425 including the metal layer 315, (b) the actual size of the corresponding dimension(s) of the IC chip 610, and/or (c) the target size of the corresponding dimension(s) of the IC chips 610. For example, the length l, width w, and/or depth d of each cavity 425 including the metal layer 315 can be no more than 20 μm larger, no more than 10 μm larger, no more than 5 μm larger, or no more than 4 μm larger than: (a) a target size of the dimension(s) of the cavities 425 including the metal layer 315, (b) the actual size of the corresponding dimension(s) of the IC chip 610, and/or (c) the target size of the corresponding dimension(s) of the IC chips 610. The laminate structure of the glass substrate 100 can provide particularly precise control of the depth d of the cavities 425 compared to conventional substrates.

In embodiments, the IC chip 610 has a grounding contact disposed on a side of the IC chip 610 that contacts the metal layer 315. For example, in embodiments, the grounding contact faces the sidewall 305 of the cavity 425 and the metal layer 315 is disposed on the sidewall 305 such that the metal layer 315 contacts the grounding contact proximate the sidewall 305. In embodiments, the grounding contact faces the floor 310 of the cavity 425 and the metal layer 315 is disposed on the floor 310 such that the metal layer 315 contacts the grounding contact proximate the floor 310.

In embodiments, the integrated circuit package 200 further comprises an electrically conductive epoxy disposed within the cavity 425 between the IC chip 610 and the metal layer 315. The electrically conductive epoxy is configured to ensure and/or enhance the electrical (and thermal) connection between the grounding contact and the metal layer 315. In embodiments, the electrically conducive epoxy comprises silver to ensure and/or enhance the electrical (and thermal) connection between the grounding contact and the metal layer 315. The integrated circuit package 200 can additionally, or alternatively, include epoxy resin (e.g., non-electrically conductive) applied between the cavity 425 and the IC chip 610.

In embodiments, a thickness of the electrically conductive epoxy is in a range of from about 3 μm to about 14 μm, or from about 3.5 μm to about 13 μm, or from about 4 μm to about 12 μm, or from about 4.5 μm to about 11 μm, or from about 5 μm to about 10 μm, or from about 5.5 μm to about 9 μm, or from about 6 μm to about 8 μm, or from about 6.5 μm to about 7 μm, and also comprising all sub-ranges and sub-values between these range endpoints.

In embodiments, the integrated circuit package 200 further comprises an insulation layer 614 disposed on the portion of the metal layer 315 disposed along the first surface 106 of the first glass cladding layer 105, on the portion of the IC chip 610 not encapsulated by the glass substrate 100 and/or the metal layer, and on the first surface 106 if any portions thereof are not covered by the metal layer 315 disposed thereon. The integrated circuit package 200 further comprises a passivation layer 318 disposed on the insulation layer 614. In embodiments, one or more of the insulation layers 614 and the passivation layer 618 comprises and electrically insulating material, such as SiO₂.

In embodiments, the insulation layer 614 and the passivation layer 618 may collectively define a redistribution layer of the integrated circuit package 200. In the embodiments shown in FIG. 10 and FIG. 11, the redistribution layer 614, 618 includes leads 620 that pass from the IC chip 610 to main contacts 622 for the IC chip 610 on an external surface 624 of the redistribution layer. As shown, the external surface 624 of the redistribution layer defines a portion of an external surface 626 of the integrated circuit package 200. The leads 620 may comprise vertical-extending electrical vias and horizontal-extending electrical interconnects that electrically connect the IC chip 610 to the main contacts 622. In embodiments, the redistribution layer 614, 618 can be manufactured using standard WLP processes.

In embodiments, the integrated circuit package 200 further comprises a contact 628 (e.g., a contact pad) disposed on the external surface 626 of the integrated circuit package. The contact 628 is configured to be thermally and electrically connected to the metal layer 315. In embodiments, as shown in FIG. 11, the integrated circuit package 200 further comprises a via 630 that extends between the metal layer 315 and the contact 628. The via 630 is configured to be thermally and electrically connected to the metal layer 315 and the contact 628. In embodiments, the contact 628 is disposed proximate to the main contacts 622 of the IC chip 610 on the external surface 624 of the redistribution layer.

The integrated circuit packages and structured glass articles with metal layers disclosed herein address the challenges of thermal management and grounding electrodes in die-embedded packaging, especially with semiconductor chips operating at high frequencies such as mmWave (e.g., >28 GHz). These mmWave chips often generate substantial heat in operation. These mmWave chips also need special consideration for grounding in the packaging structure and process design since the ground contacts thereof are typically located on the surface opposite to the main electrical contacts of the chips.

The integrated circuit packages of the present disclosure comprise structured glass articles with precision cavities formed therein. The integrated circuit packages further comprise a metal layer, such as a layer of copper, deposited within the cavities where the mmWave chips are mounted and along surfaces of the structured glass articles. The thin metal layer in the various embodiments disclosed herein can function both for heat dissipation and providing ground electrodes without additional processes, such as forming metallized through vias. Since the thermal conductivity of copper is hundreds to thousands of times higher than that of conventional organic mold compounds and/or glass, the metal layer can be deposited in the thickness ranges disclosed herein and still significantly improve heat dissipation capability. The electrically conductive epoxy resin can also be used to form ground contacts to the deposited copper layer inside the cavity.

While the disclosure has been illustrated and described in detail in the drawings and foregoing description, the same should be considered as illustrative and not restrictive in character. It is understood that only the preferred embodiments have been presented and that all changes, modifications, and further applications that come within the spirit of the disclosure are desired to be protected.

What is claimed is:

1. An integrated circuit package, comprising:
a glass substrate comprising a glass cladding layer fused to a glass core layer;
a cavity formed in the glass substrate, the cavity having a floor defined by the glass core layer and a sidewall defined by the glass cladding layer;
a metal layer configured to define a continuous path of thermally and electrically conductive material disposed within the cavity and along a first surface of the glass cladding layer, the first surface facing opposite an interface between the glass core layer and the glass cladding layer; and
an integrated circuit chip disposed within the cavity and contacting a portion of the metal layer within the cavity.

2. The integrated circuit package of claim 1, wherein the metal layer is disposed on an entirety of the sidewall within the cavity.

3. The integrated circuit package of claim 1, wherein the metal layer is disposed on a portion of the floor.

4. The integrated circuit package of claim 1, wherein the metal layer is disposed on an entirety of the floor.

5. The integrated circuit package of claim 1, wherein the metal layer is disposed on an entirety of the first surface of the glass cladding layer.

6. The integrated circuit package of claim 1, wherein the metal layer comprises a layer of aluminum, a layer of copper, a layer of graphene, a layer of titanium, or a combination thereof.

7. The integrated circuit package of claim 1, wherein the metal layer comprises a layer of copper and one or more of graphene and carbon.

8. The integrated circuit package of claim 1, wherein a thickness of the metal layer is in a range of from about 1 μm to about 20 μm.

9. The integrated circuit package of claim 1, wherein a thickness of the metal layer is based on a driving power of the integrated circuit chip.

10. The integrated circuit package of claim 9, wherein the thickness of the metal layer is in a range of from 8 to 12 times the driving power of the integrated circuit chip.

11. The integrated circuit package of claim 9, wherein the driving power of the integrated circuit chip is in a range of from about 0.25 W to about 2 W.

12. The integrated circuit package of claim 1, wherein an operating frequency of the integrated circuit chip is equal to or greater than about 28 GHz.

13. The integrated circuit package of claim 1, further comprising an electrically conductive epoxy disposed within the cavity between the integrated circuit chip and the metal layer.

14. The integrated circuit package of claim 13, wherein one or more of:
the electrically conductive epoxy comprises silver, and
a thickness of the electrically conductive epoxy is in a range of from about 3.5 μm to about 13 μm.

15. The integrated circuit package of claim 1, wherein the integrated circuit chip has a grounding contact disposed on a side of the integrated circuit chip facing the floor of the cavity.

16. The integrated circuit package of claim 1, further comprising:
a contact disposed on an external surface of the integrated circuit package, the contact thermally and electrically connected to the metal layer, and
a via that extends between the metal layer and the contact, the via thermally and electrically connected to the metal layer and the contact,
wherein the contact is disposed proximate to main contacts of the integrated circuit chip on the external surface, the main contacts electrically connected to the integrated circuit chip.

17. The integrated circuit package of claim 1, further comprising an insulation layer disposed over the integrated circuit chip, the first surface, and the portion of the metal layer disposed along the first surface.

18. The integrated circuit package of claim 1, further comprising a passivation layer disposed on the insulation layer.

19. The integrated circuit package of claim 18, wherein one or more of insulation layer and the passivation layer comprises an electrically insulating material, and wherein the electrically insulating material comprises SiO₂.

20. The integrated circuit package of claim 1, wherein the sidewall of the cavity is substantially perpendicular to the floor of the cavity.
